(19) United States
(12) Patent Application Publication
(10) Pub. No.: US 2020/0083397 A1
(43) Pub. Date: Mar. 12, 2020

(54) DISPLAY APPARATUS AND MANUFACTURING METHOD THEREOF

(71) Applicant: SAMSUNG ELECTRONICS CO., LTD., Suwon-si (KR)

(72) Inventors: Tack Mo LEE, Suwon-si (KR); Jung Hoon Yoon, Suwon-si (KR); Gi Tae Kim, Suwon-si (KR); Won Yong Lee, Suwon-si (KR); Won Soon Park, Suwon-si (KR)

(73) Assignee: SAMSUNG ELECTRONICS CO., LTD., Suwon-si (KR)

(21) Appl. No.: 16/564,111

(22) Filed: Sep. 9, 2019

(30) Foreign Application Priority Data
Sep. 10, 2018 (KR) 10-2018-0107686

(51) Int. Cl. H01L 33/00; H01L 27/15; H01L 33/52

(52) U.S. Cl. CPC H01L 33/005; H01L 2933/005; H01L 33/52; H01L 27/156

(57) ABSTRACT

A manufacturing method of a display apparatus includes mounting a plurality of inorganic light emitting diodes on a substrate, forming a black molding layer having a low refractive index and configured to surround the plurality of inorganic light emitting diodes such that front light emitting surfaces of the plurality of inorganic light emitting diodes that are directed to a front side of the display apparatus are exposed, and assembling a plurality of unit modules each comprising the substrate, the plurality of inorganic light emitting diode, and the black molding layer to be adjacent to each other.

### CROSS-REFERENCE TO RELATED APPLICATION(S)

This application is based on and claims priority under 35 U.S.C. § 119 to Korean Patent Application No. 10-2018-0107686, filed on Sep. 10, 2018, in the Korean Intellectual Property Office, the disclosure of which is incorporated by reference herein in its entirety

### BACKGROUND

### 1. Field

The disclosure relates to a display apparatus and a manufacturing method thereof, and, more particularly, to a display apparatus in which an inorganic light emitting diode is directly mounted on a substrate, and a manufacturing method thereof.

### 2. Description of Related Art

A display apparatus is a kind of an output device that visually displays data information such as characters and figures, and images, and the demand for high luminance, high resolution, large size, high efficiency, and low power display apparatuses is continuously increasing. Accordingly, an Organic Light Emitting Diode (OLED) panel has been popular as a new display apparatus that replaces a Liquid Crystal Display (LCD), but the OLED has some difficulties to be solved such as the high price caused by a low production yield rate, securing the reliability of large size panel, and securing the durability that is affected by external environment such as moisture.

As a new product that replaces or supplements the LCD panel and the OLED panel, a study of a new technology for manufacturing a panel by directly mounting an inorganic light emitting diode emitting red (R), green (G) and blue (B) light, on a substrate has been conducted. The inorganic light emitting display technology has many difficulties in transferring an inorganic light emitting diode having a size of several micrometers to several hundreds of micrometers from a wafer to a substrate. However, even after the inorganic light emitting diode is mounted on a substrate, there are still difficulties in physically protecting the inorganic light emitting diode without the optical distortion and the optical loss. Further, there is a need for a technology that can improve image quality in addition to a technology for simply protecting the inorganic light emitting diode.

### SUMMARY

It is an aspect of the present disclosure to provide a display apparatus including an improved structure capable of improving bonding reliability of inorganic light emitting diodes and capable of reducing a speckle noise caused by inorganic light emitting diodes mounted on a substrate in a tilted state, and a manufacturing method thereof.

It is another aspect of the present disclosure to provide a display apparatus including an improved structure capable of reducing right and left viewing angles and capable of preventing a seam between unit modules adjacent to each other from being seen, and a manufacturing method thereof.

Additional aspects of the present disclosure will be set forth in part in the description which follows and, in part, will be obvious from the description, or may be learned by practice of the present disclosure.

In accordance with an aspect of the disclosure, a manufacturing method of a display apparatus includes mounting a plurality of inorganic light emitting diodes on a substrate, forming a black molding layer having a low refractive index and configured to surround the plurality of inorganic light emitting diodes such that front light emitting surfaces of the plurality of inorganic light emitting diodes that are directed to a front side of the display apparatus are exposed, and assembling a plurality of unit modules each including the substrate, the plurality of inorganic light emitting diode, and the black molding layer, to be adjacent to each other.

Side surfaces of the plurality of inorganic light emitting diodes may be covered with the black molding layer.

The black molding layer may have a refractive index of 1.40 or ore and 1.58 or less.

The black molding layer may include at least one of a thermosetting material and a photosensitive material.

The thermosetting material may include at least one of silicon, epoxy, ethylene-vinyl acetate copolymer (EVA), polyvinyl butyral (PVB), and urethane.

A width and a length of the plurality of inorganic light emitting diodes each may have a size of several micrometers to several hundreds of micrometers.

A first contact electrode and a second contact electrode of the plurality of inorganic light emitting diodes may be connected to electrodes of the substrate through soldering.

The forming the black molding layer may include forming the black molding layer by supplying a black molding liquid onto the substrate, and curing the black molding layer.

The forming the black molding layer may include forming the black molding layer by arranging a black film on the substrate to cover the plurality of inorganic light emitting diodes and allowing the black molding layer to be exposed to light such that the front light emitting surfaces of the plurality of inorganic light emitting diodes are exposed to outside.

The manufacturing method may further include arranging a transparent molding layer on the black molding layer to protect the plurality of inorganic light emitting diodes.

The manufacturing method may further include arranging a black optical film on the transparent molding layer to improve optical characteristics of the plurality of inorganic light emitting diodes.

The manufacturing method may further include forming the black molding layer to cover the substrate, forming assembly surfaces of the plurality of unit modules by cutting a spare portion of the black molding layer that is placed out of the substrate, and assembling the plurality of unit modules such that the assembly surfaces face each other.

The manufacturing method may further include arranging a dam to be adjacent to the substrate and forming the black molding layer in a space that is defined by the substrate and the dam.

The manufacturing method may further include curing the black molding layer, removing the dam and assembling the plurality of unit modules such that assembly surfaces of the plurality of unit modules, which are formed by the dam, face each other.

The assembling the plurality of unit modules to be adjacent to each other may include arranging the plurality of unit modules in a matrix form.

In accordance with another aspect of the disclosure, a display apparatus includes a plurality of unit modules and a frame configured to support the plurality of unit modules, and each of the plurality of unit modules includes a substrate, a plurality of inorganic light emitting diodes mounted on the substrate, and a black molding layer having a low refractive index and configured to surround side surfaces of the plurality of inorganic light emitting diodes such that light generated by the plurality of inorganic light emitting diodes is emitted through front light emitting surfaces of the plurality of inorganic light emitting diodes that are directed to a front side of the display apparatus.

The black molding layer may have a refractive index of 1.40 or more and 1.58 or less.

The black molding layer may include at least one of a thermosetting material and a photosensitive material.

A width and a length of the plurality of inorganic light emitting diodes each may have a size of several micrometers to several hundreds of micrometers.

The plurality of unit modules may be assembled to each other and may be arranged in a matrix form.

### BRIEF DESCRIPTION OF THE DRAWINGS

These and/or other aspects of the disclosure will become apparent and more readily appreciated from the following description of embodiments, taken in conjunction with the accompanying drawings of which:

FIG. 1 is a perspective view of a display apparatus according to an embodiment of the disclosure;

FIG. 2 is a front view illustrating a state in which a plurality of unit modules are arranged in a matrix according to an embodiment of the disclosure;

FIG. 3 is a front view of a single unit module according to an embodiment of the disclosure;

FIG. 4 is a flow chart illustrating a first manufacturing method of the display apparatus according to an embodiment of the disclosure;

FIGS. 5A to 5E are views illustrating a manufacturing process according to the first manufacturing method of FIG. 4;

FIG. 6 is a flow chart illustrating a second manufacturing method of the display apparatus according to an embodiment of the disclosure;

FIGS. 7A to 7E are views illustrating a manufacturing process according to the second manufacturing method of FIG. 6;

FIG. 8 is a flow chart illustrating a third manufacturing method of the display apparatus according to an embodiment of the disclosure;

FIGS. 9A to 9D are views illustrating a manufacturing process according to the third manufacturing method of FIG. 8;

FIG. 10 is a flow chart illustrating a fourth manufacturing method of the display apparatus according to an embodiment of the disclosure; and

FIGS. 11A to 11D are views illustrating a manufacturing process according to the fourth manufacturing method of FIG. 10.

### DETAILED DESCRIPTION

Hereinafter, embodiments of the disclosure will be described with reference to drawings. In the following detailed description, the terms of “front end”, “rear end”, “upper portion”, “lower portion”, “upper end”, “lower end” and the like may be defined by the drawings, but the shape and the location of the component is not limited by the term.

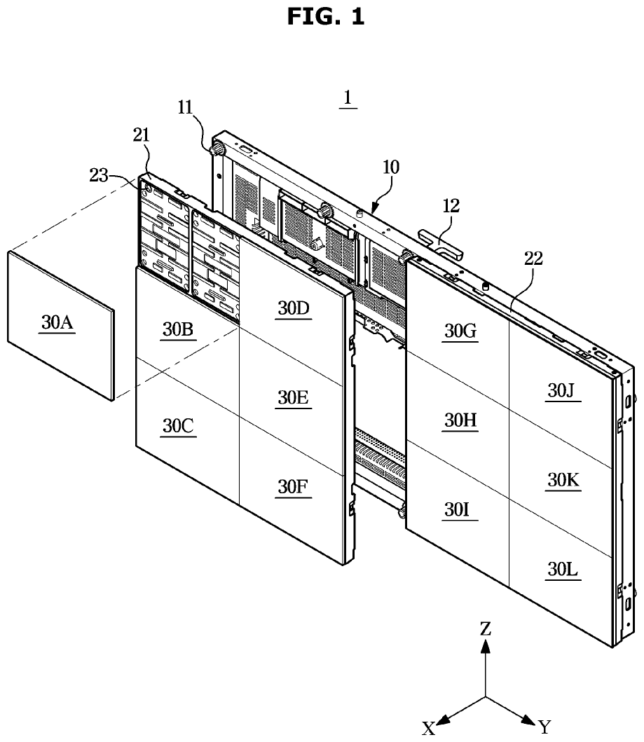

FIG. 1 is a perspective view of a display apparatus according to an embodiment of the disclosure. In FIG. 1, “X” represents a front and rear direction, “Y” represents a left and right direction, and “Z” represents an up and down direction.

Referring to FIG. 1, a display apparatus 1 is a device for displaying information, materials, and data as the form of characters, features, graphics, and image, and a television (TV), a personal computer (PC), a mobile, and a digital signage may be implemented by the display apparatus 1. The display apparatus 1 may be installed on the ground by a stand (not shown) or may be installed on a wall.

According to an embodiment, the display apparatus 1 may include a cabinet 10, a plurality of unit modules 30A˜30L installed in the cabinet 10, and frames 21 and 22 connecting the cabinet 10 to the plurality of unit modules 30A˜30L. The cabinet 10 may support the plurality of unit modules 30A˜30L and form a part of an outer appearance of the display apparatus 1. The cabinet 10 may be provided with a handle 12 for movement.

The plurality of unit modules 30A˜30L may be arranged in an M*N matrix in the up, down, left, and right directions so as to be adjacent to each other. According to an embodiment, the plurality of unit modules 30A˜30L may be formed in such a way that 12 unit modules are coupled to the cabinet 10 in the form of a 4*3 matrix, but the number and arrangement of a plurality of unit modules are not limited thereto. Some unit modules 30A˜30F of the plurality of unit modules 30A˜30L may be installed in the cabinet 10 via the frame 21, and remaining unit modules 30G˜30L may be installed in the cabinet 10 via the other frame 22.

The cabinet 10 and the frames 21 and 22 may be provided with a cabinet coupling portion 11 and a frame coupling portion 23, respectively so that the unit modules 30A˜30L are installed in the cabinet 10. The cabinet coupling portion 11 and the frame coupling portion 23 may be coupled to each other through various known methods such as a magnetic force using a magnet or a mechanical fitting structure.

The display apparatus 1 may further include a control board (not shown) for driving the plurality of unit modules 30A˜30L and a power supply device (not shown) for supplying power to the plurality of unit modules 30A˜30L.

The unit modules 30A˜30L may be planar or curved. Furthermore, the curvature thereof may vary.

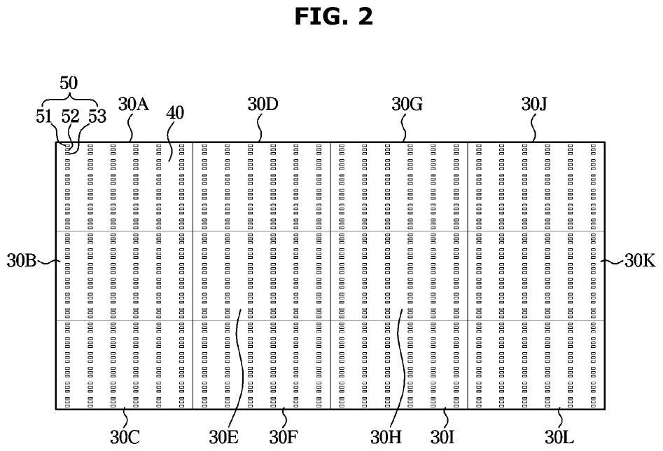

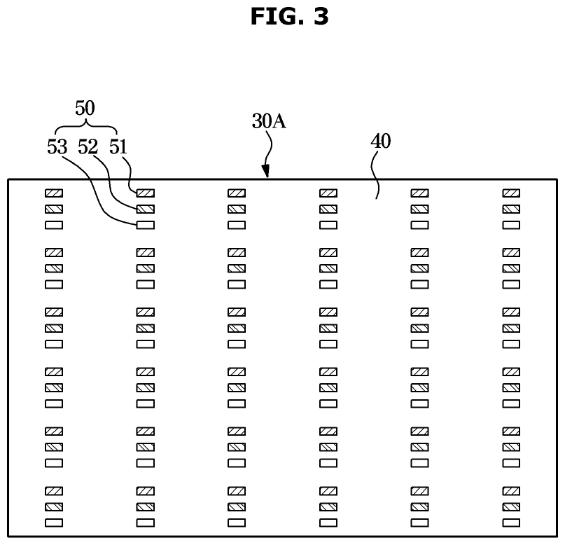

FIG. 2 is a front view illustrating a state in which a plurality of unit modules are arranged in a matrix according to an embodiment of the disclosure. FIG. 3 is a front view of a single unit module according to an embodiment of the disclosure.

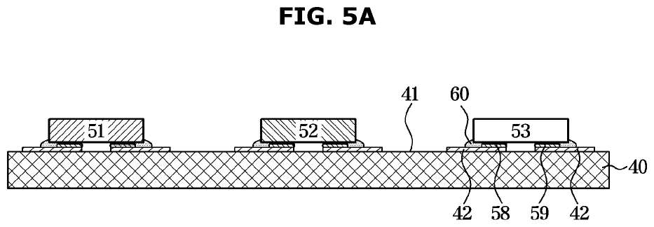

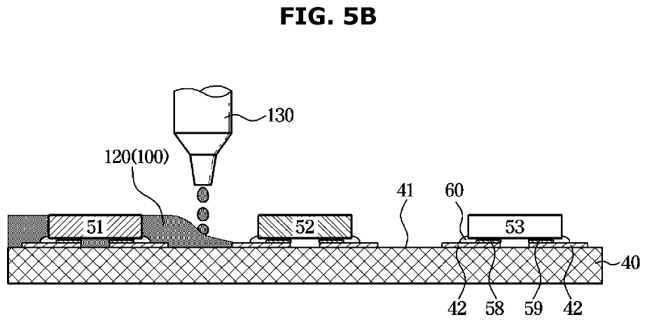

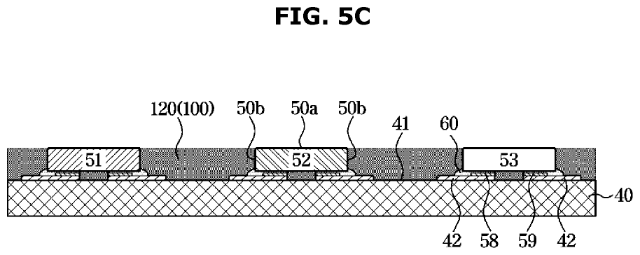

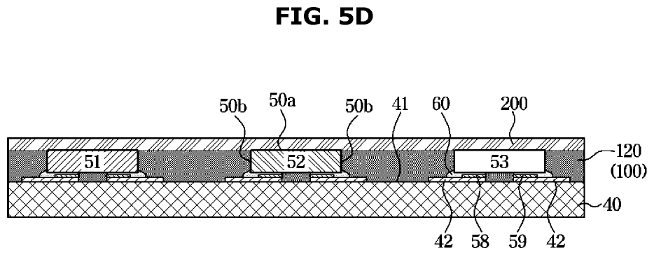

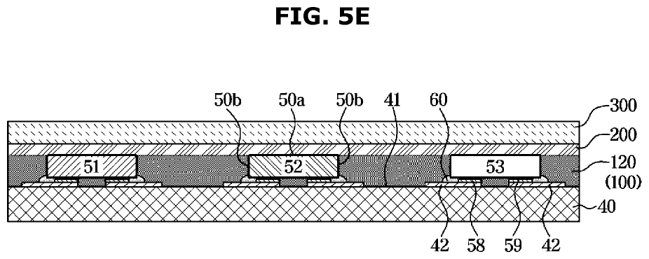

As illustrated in FIGS. 2 and 3, the unit modules 30A˜30L each may include a substrate 40 and a plurality of inorganic light emitting diodes 50 mounted on a mounting surface 41 (see, FIG. 5A) of the substrate 40. Each of the plurality of inorganic light emitting diodes 50 may include a p-n diode, a first contact electrode 58 (see, FIG. 5A), and a second contact electrode 59 (see, FIG. 5A).

The substrate 40 may be formed of a material such as polyimide (PI), FR4, and glass. On the mounting surface 41 of the substrate 40, a pattern for forming a driving circuit, and electrodes 42 (see, FIG. 5A) may be formed. The first contact electrode 58 and the second contact electrode 59 of the plurality of inorganic light emitting diodes 50 may be soldered to the electrodes 42 formed on the substrate 40.

The inorganic light emitting diode 50 may be formed of an inorganic material. Therefore, the inorganic light emitting diode 50 may have higher durability and a longer lifetime than the organic light emitting diode (OLED), which is based on organic materials, and the inorganic light emitting diode 50 may have the power efficiency several times higher than that of the OLED. The inorganic light emitting diode 50 may include LED.

The plurality of inorganic light emitting diodes 50 may include a red inorganic light emitting diode 51, a green inorganic light emitting diode 52, and a blue inorganic light emitting diode 53. The plurality of inorganic light emitting diodes 50 may be formed by mounting a series of the red inorganic light emitting diode 51, the green inorganic light emitting diode 52 and the blue inorganic light emitting diode 53 as a unit, on the substrate 40. The red inorganic light emitting diode 51, the green inorganic light emitting diode 52 and the blue inorganic light emitting diode 53 may form a single pixel.

The red inorganic light emitting diode 51, the green inorganic light emitting diode 52 and the blue inorganic light emitting diode 53 may be arranged at a predetermined interval in a row as illustrated in the drawings, but it may be arranged in the other forms.

The plurality of inorganic light emitting diodes 50 may be picked up from a wafer and transferred directly onto the substrate 40. The plurality of inorganic light emitting diodes 50 may be picked up and transferred through an electrostatic method using an electrostatic head or a bonding method using an elastic polymer such as PDMS or silicon as a head. A width, a length, and a height of the plurality of inorganic light emitting diodes 50 each may have a size of several micrometers to several hundreds of micrometers.

The plurality of inorganic light emitting diodes 50 may be formed in the form of a flip chip in which the first contact electrode 58 and the second contact electrode 59 are arranged in the same direction. The first and second contact electrodes 58 and 59 of the plurality of inorganic light emitting diodes 50 may be connected to the electrodes 42 of the substrate 40 through soldering.

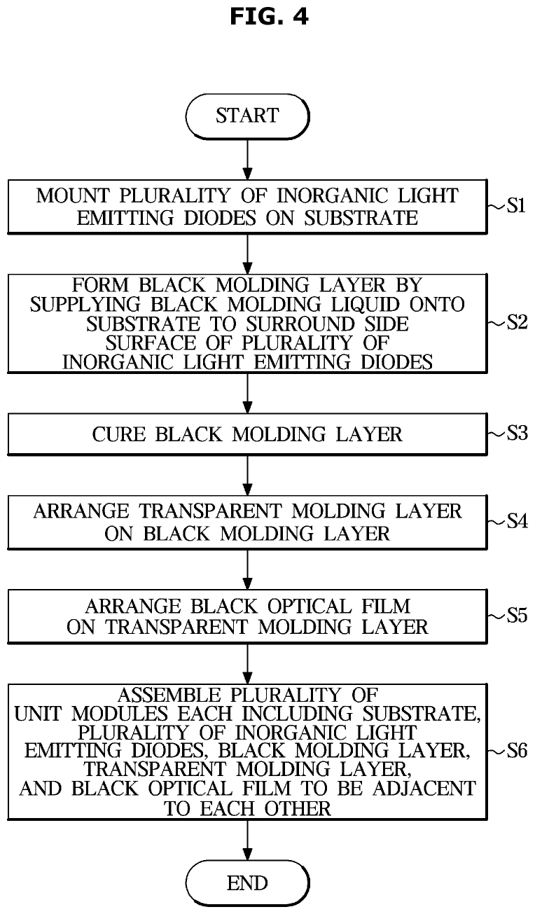

FIG. 4 is a flow chart illustrating a first manufacturing method of the display apparatus according to an embodiment of the disclosure. Hereinafter, the first manufacturing method will be described with reference to FIGS. 5A-5E.

As illustrated in FIG. 4, a manufacturing method of the display apparatus 1 may include mounting the plurality of inorganic light emitting diodes 50 on the substrate 40 (51). In this case, the first contact electrode 58 and the second contact electrode 59 of the plurality of inorganic light emitting diodes 50 may be connected to the electrodes 42 of the substrate 40 through soldering.

The manufacturing method of the display apparatus 1 may further include forming a black molding layer 100 by supplying a black molding liquid 120 onto the substrate 40 so as to surround side surfaces 50b of the plurality of inorganic light emitting diodes 50 (S2).

The manufacturing method of the display apparatus 1 may further include curing the black molding layer 100 (S3).

The manufacturing method of the display apparatus 1 may further include arranging a transparent molding layer 200 on the black molding layer 100 (S4).

The manufacturing method of the display apparatus 1 may further include arranging a black optical film 300 on the transparent molding layer 200 (S5).

The manufacturing method of the display apparatus 1 may further include assembling the plurality of unit modules 30A-30L each including the substrate 40, the plurality of inorganic light emitting diodes 50, the black molding layer 100, the transparent molding layer 200, and the black optical film 300 to be adjacent to each other (S6).

Hereinafter, the first manufacturing method of the display apparatus 1 will be described in detail.

FIGS. 5A to 5E are views illustrating a manufacturing process according to the first manufacturing method of FIG. 4. Hereinafter, for convenience of description, a state in which the red inorganic light emitting diode 51, the green inorganic light emitting diode 52, and the blue inorganic light emitting diode 53 are mounted on the substrate 40 will be mainly described. Hereinafter, a drawing illustrating of assembling the plurality of unit modules 30A-30L to each other will be omitted.

As illustrated in FIG. 5A, the plurality of inorganic light emitting diodes 50 may be mounted on the substrate 40. The plurality of inorganic light emitting diodes 50 may be mounted on the mounting surface 41 of the substrate 40 to be spaced apart from each other at a predetermined distance. The first contact electrode 58 and the second contact electrode 59 of the plurality of inorganic light emitting diodes 50 may be connected to the electrodes 42 formed on the substrate 40 by a solder 60.

As illustrated in FIGS. 5B and 5C, the black molding layer 100 may be formed to surround the plurality of inorganic light emitting diodes 50 on the substrate 40. The black molding layer 100 may be formed on the substrate 40 to surround the side surfaces 50b of the plurality of inorganic light emitting diodes 50. In other words, the black molding layer 100 may be formed on the substrate 40 in such a way that front light emitting surfaces 50a of the plurality of inorganic light emitting diodes 50 directed the front of the display apparatus 1 are exposed. That is, the black molding layer 100 may be formed to surround the side surfaces 50b of the plurality of inorganic light emitting diodes 50, except for the front light emitting surfaces 50a of the plurality of inorganic light emitting diodes 50.

As illustrated in FIG. 5B, the black molding liquid 120 may be supplied to the substrate 40 to form the black molding layer 100. The black molding liquid 120 may be applied, coated, or jetted onto the substrate 40 by a molding liquid supplier 130. The black molding liquid 120 may be printed on the substrate 40 by the molding liquid supplier 130. A method in which the black molding liquid 120 is supplied to the substrate 40 is not limited to the above example and thus the method may vary.

As illustrated in FIG. 5C, the black molded layer 100 may be formed on the substrate 40 in such a way that the black molded layer 100 covers other surfaces of the plurality of inorganic light emitting diodes 50, except for the front light emitting surfaces 50a of the plurality of inorganic light emitting diodes 50, and then the black molded layer 100 may be cured. For example, the black molding layer 100 may be cured by at least one of thermal curing and UV curing.

As illustrated in FIG. 5D, the transparent molding layer 200 may be arranged on the black molded layer 100 to protect the plurality of inorganic light emitting diodes 50. The transparent molding layer 200 may be disposed on the black molding layer 100 to physically protect the plurality of inorganic light emitting diodes 50 without optical distortion. As an example, the transparent molding layer 200 may be formed of a transparent material such as epoxy or silicone.

As illustrated in FIG. 5E, the black optical film 300 may be disposed on the transparent molding layer 200 to improve optical characteristics of the plurality of inorganic light emitting diodes 50. The black optical film 300 may be arranged to maintain the black impression and to lower the reflectance when the display apparatus 1 is turned off. As an example, the black optical film 300 may include a neutral density (ND) film), a circularly polarizing film, and a film capable of exhibiting the black impression by using a liquid coating.

The black molding layer 100 may have a low refractive index. The black molding layer 100 may have a refractive index of 1.40 or more and 1.58 or less. For example, when the black molding layer 100 is formed of an epoxy material, the black molding layer 100 may have a refractive index of 1.50 or more and 1.58 or less. The black molding layer 100 may have a refractive index of 1.50 or more and 1.51 or less when the black molding layer 100 is formed of an epoxy material. As another example, when the black molding layer 100 is formed of a silicon material, the black molding layer 100 may have a refractive index of 1.40 or more and 1.58 or less. The black molding layer 100 has a refractive index of 1.40 or more and 1.51 or less when the black molding layer 100 is formed of a silicon material.

The black molding layer 100 may include a base material and a black pigment. The base material may include at least one of a thermosetting material and a photosensitive material. As an example, the thermosetting material may include at least one of silicon, epoxy, ethylene-vinyl acetate copolymer (EVA), polyvinyl butyral (PVB) or urethane. As an example, the photosensitive material may include a photosensitive material capable of utilizing a photolithography process.

The black molding layer 100 may be implemented by a liquid or solid material. The black molding liquid 120 described in FIGS. 5A to 5E illustrates an example of the liquid material for forming the black molding layer 100. Alternatively, the black molding layer 100 may be implemented by a material in the form of a film. However, the material of the black molding layer 100 is not limited thereto and thus the material of the black molding layer 100 may vary.

As described above, when the side surfaces 50b of the plurality of inorganic light emitting diodes 50 are covered with the black molding layer 100 having a low refractive index, it is possible to effectively reduce a speckle noise caused by the tilting of the plurality of inorganic light emitting diodes 50. The speckle noise is a phenomenon in which a screen of the display apparatus appears to be shiny according to an angle. For example, in a state in which the side surfaces 50b of the plurality of inorganic light emitting diodes 50 are surrounded by the black molding layer having a refractive index of 1.48, the light may be emitted to the outside of the display apparatus and thus the speckle noise may occur when the plurality of inorganic light emitting diodes 50 are tilted. On the other hand, in a state in which the side surfaces 50b of the plurality of inorganic light emitting diodes 50 are surrounded by the black molding layer having a refractive index of 1.58, the light may be not emitted to the outside of the display apparatus and thus the speckle noise may not occur although the plurality of inorganic light emitting diodes 50 are tilted.

When the side surfaces 50b of the plurality of inorganic light emitting diodes 50 are covered with the black molding layer 100, light emitting regions of the plurality of inorganic light emitting diodes 50 may be changed from a rear end portion of the plurality of inorganic light emitting diodes 50 to a front end portion of the plurality of inorganic light emitting diodes 50. That is, when the side surfaces 50b of the plurality of inorganic light emitting diodes 50 are covered with the black molding layer 100, the light generated from the plurality of inorganic light emitting diodes 50 may be blocked by the black molding layer 100, and thus the light may be not emitted to the outside of the display apparatus 1 through the side surfaces 50b of the plurality of inorganic light emitting diodes 50. Therefore, the light may be emitted to the outside of the display apparatus 1 through the front light emitting surface 50a of the plurality of inorganic light emitting diodes 50. Accordingly, the right and left viewing angles may be reduced and the seam between adjacent unit modules may be prevented from being seen.

When the solder 60 is also formed to have a black color like the black molding layer 100, it is possible to maintain the black impression in an off state of the display apparatus 1 and to expect the improvement of the image quality contrast ratio in an on state of the display apparatus 1.

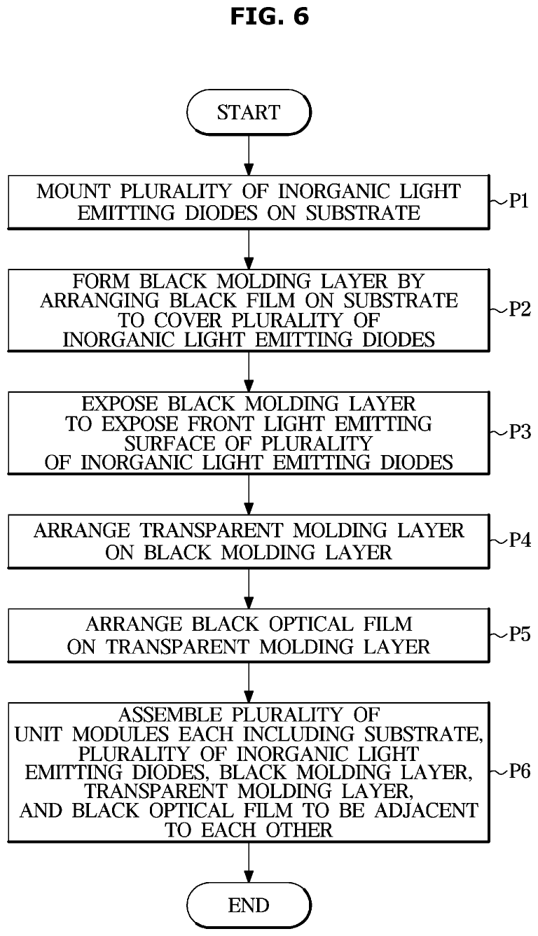

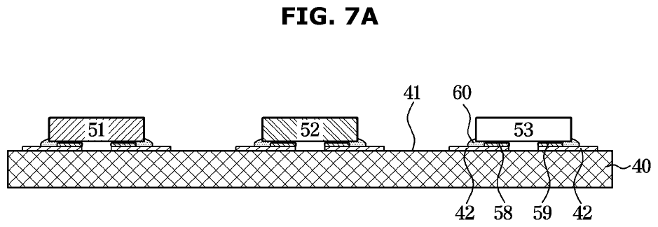

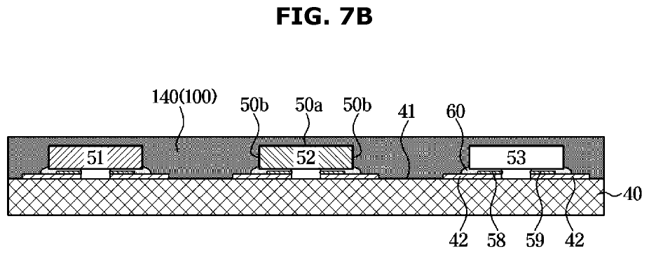

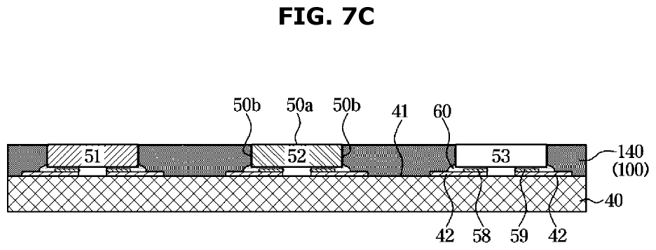

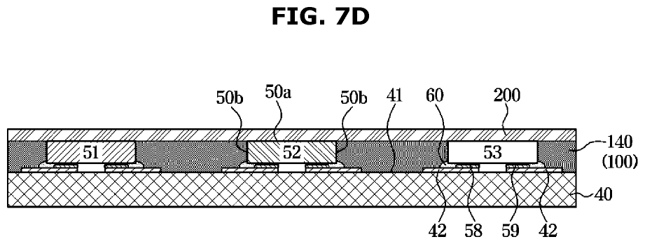

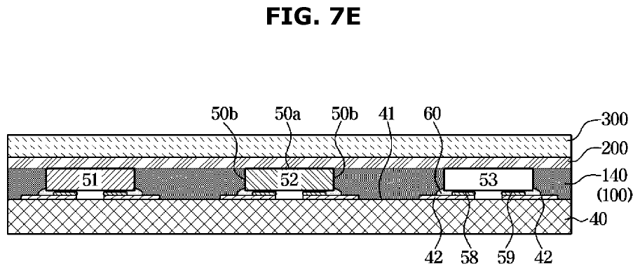

FIG. 6 is a flow chart illustrating a second manufacturing method of the display apparatus according to an embodiment of the disclosure. Hereinafter, the second manufacturing method will be described with reference to FIGS. 7A to 7E.

As illustrated in FIG. 6, a manufacturing method of the display apparatus 1 may include mounting the plurality of inorganic light emitting diodes 50 on the substrate 40 (P1). In this case, the first contact electrode 58 and the second contact electrode 59 of the plurality of inorganic light emitting diodes 50 may be connected to the electrodes 42 of the substrate 40 through soldering.

The manufacturing method of the display apparatus 1 may further include forming the black molding layer 100 by arranging a black film 140 on the substrate 40 to cover the plurality of inorganic light emitting diodes 50 (P2). In this case, the black film 140 may be laminated on the substrate 40 to cover both the front light emitting surfaces 50a and the side surfaces 50b of the plurality of inorganic light emitting diodes 50.

The manufacturing method of the display apparatus 1 may further include allowing the black molding layer 100 to be exposed to light such that the front light emitting surfaces 50a of the plurality of inorganic light emitting diodes 50 are exposed to outside (P3). The manufacturing method of the display apparatus 1 may further include exposing and developing the black molding layer 100 so that the front light emitting surfaces 50a of the plurality of inorganic light emitting diodes 50 are exposed.

The manufacturing method of the display apparatus 1 may further include arranging the transparent molding layer 200 on the black molding layer 100 (P4).

The manufacturing method of the display apparatus 1 may further include arranging the black optical film 300 on the transparent molding layer 200 (P5).

The manufacturing method of the display apparatus 1 may further include assembling the plurality of unit modules 30A-30L each including the substrate 40, the plurality of inorganic light emitting diodes 50, the black molding layer 100, the transparent molding layer 200, and the black optical film 300 to be adjacent to each other (P6).

Hereinafter, the second manufacturing method of the display apparatus 1 will be described in detail.

FIGS. 7A to 7E are views illustrating a manufacturing process according to the second manufacturing method of FIG. 6. Hereinafter, description of the same as the first manufacturing method of the display apparatus 1 will be omitted. Hereinafter, the drawing of assembling the plurality of unit modules 30A-30L together will be omitted.

As illustrated in FIG. 7A, the plurality of inorganic light emitting diodes 50 may be mounted on the substrate 40. A description thereof is the same as those shown in FIG. 5A and thus it will be omitted.

As illustrated in FIGS. 7B and 7C, the black molding layer 100 may be formed on the substrate 40 to cover the plurality of inorganic light emitting diodes 50. The black molding layer 100 may be formed on the substrate 40 to completely cover the plurality of inorganic light emitting diodes 50, that is, the black molding layer 100 may be formed on the substrate 40 to surround both of the front light emitting surfaces 50a and the side surfaces 50b of the plurality of inorganic light emitting diodes 50.

As illustrated in FIG. 7B, the black molding layer 100 may be implemented in the form of the black film 140. The black film 140 may be disposed on the substrate 40 to cover the plurality of inorganic light emitting diodes 50. At this time, the light generated from the plurality of inorganic light emitting diodes 50 is blocked by the black film 140 covering the four sides of the plurality of inorganic light emitting diodes 50, and thus the light may be not emitted to the outside of the display apparatus 1.

As illustrated in FIG. 7C, the black film 140 may be exposed so that the front light emitting surfaces 50a of the plurality of inorganic light emitting diodes 50 are exposed, and thus the black molding layer 100 may be formed through an exposure operation and a development operation. At this time, the light generated from the plurality of inorganic light emitting diodes 50 may be emitted to the outside of the display apparatus 1 through the front light emitting surfaces 50a of the plurality of inorganic light emitting diodes 50.

As illustrated in FIG. 7D, the transparent molding layer 200 may be arranged on the black molding layer 100 to protect the plurality of inorganic light emitting diodes 50. A description thereof is the same as those shown in FIG. 5D and thus it will be omitted.

As illustrated in FIG. 7E, the black optical film 300 may be disposed on the transparent molding layer 200 to improve the optical characteristics of the plurality of inorganic light emitting diodes 50. A description thereof is the same as those shown in FIG. 5E and thus it will be omitted.

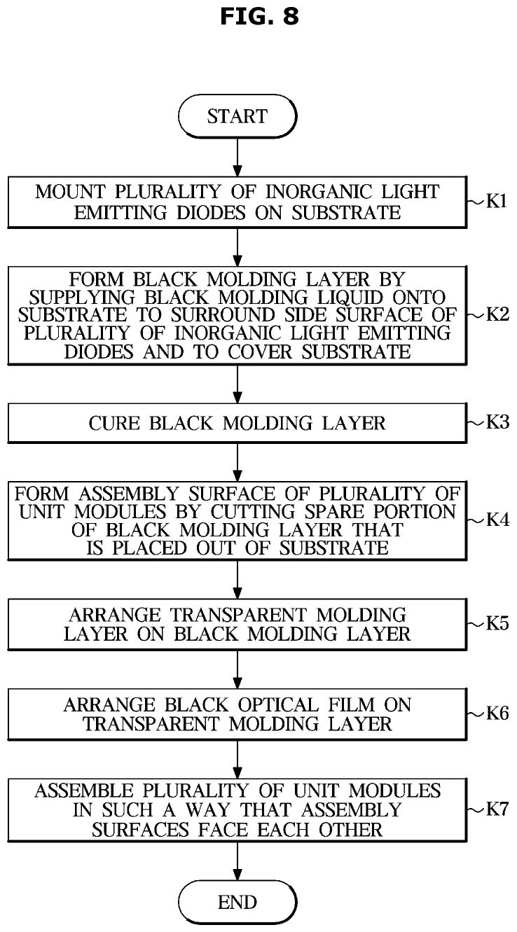

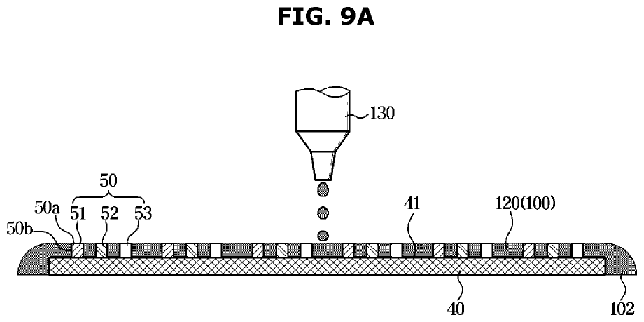

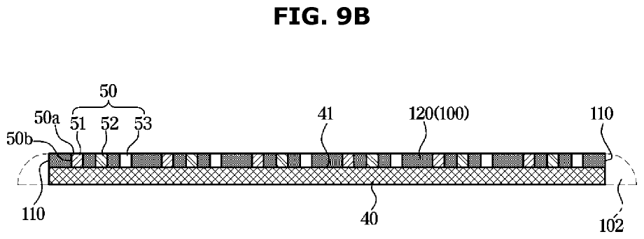

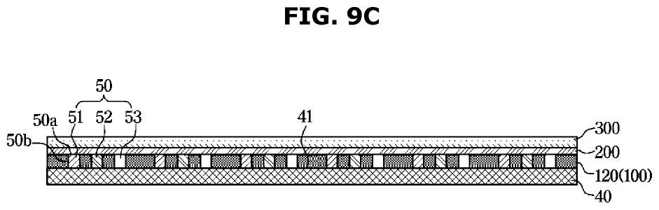

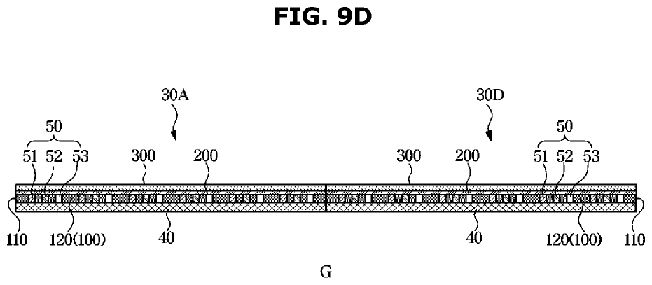

FIG. 8 is a flow chart illustrating a third manufacturing method of the display apparatus according to an embodiment of the disclosure and FIGS. 9A to 9D are views illustrating a manufacturing process according to the third manufacturing method of FIG. 8. The third manufacturing method of the display apparatus 1 is a method of manufacturing the display apparatus 1 by assembling a plurality of unit modules 30A-30L manufactured by the first manufacturing method of the display apparatus 1. Hereinafter, for convenience of description, the plurality of unit modules 30A-30L manufactured by the first manufacturing method of the display apparatus 1 will be mainly described, but alternatively may be manufactured by the second manufacturing method of the display apparatus 1. Hereinafter, FIGS. 1 to 5E may be referred to for reference numerals not shown in FIGS. 9A to 9D. Hereinafter, a case where the unit module 30A and the unit module 30D are assembled will be described as an example.

As illustrated in FIG. 8, a manufacturing method of the display apparatus 1 may include mounting the plurality of inorganic light emitting diodes 50 on the substrate 40 (K1). In this case, the first contact electrode 58 and the second contact electrode 59 of the plurality of inorganic light emitting diodes 50 may be connected to the electrodes 42 of the substrate 40 through soldering.

As illustrated in FIGS. 8 and 9A, the manufacturing method of the display apparatus 1 may further include forming the black molding layer 100 by supplying the black molding liquid 120 onto the substrate 40 so as to surround the side surfaces 50b of the plurality of inorganic light emitting diodes 50 (K2). The black molding liquid 120 may be supplied on the substrate 40 to overflow. That is, the black molding liquid 120 may be supplied on the substrate 40 sufficiently to overflow from the substrate 40.

The manufacturing method of the display apparatus 1 may further include curing the black molding layer 100 (K3).

As illustrated in FIGS. 8 and 9B, the manufacturing method of the display apparatus 1 may further include forming an assembly surfaces 110 of the plurality of unit modules 30A-30L by cutting a spare portion 102 of the black molding layer 100 that is placed out of the substrate 40 (K4). The assembly surfaces 110 of the plurality of unit modules 30A-30L may be flat.

As illustrated in FIGS. 8 and 9C, the manufacturing method of the display apparatus 1 may further include arranging the transparent molding layer 200 on the black molding layer 100 (K5).

As illustrated in FIGS. 8 and 9C, the manufacturing method of the display apparatus 1 may further include arranging the black optical film 300 on the transparent molding layer 200 (K6).

As illustrated in FIGS. 8 and 9D, the manufacturing method of the display apparatus 1 may further include assembling the plurality of unit modules 30A-30L such that the respective assembly surfaces 110 faces each other (K7). Assembling the plurality of unit modules 30A-30L to be adjacent to each other may include arranging a plurality of unit modules 30A-30L in a matrix form. A seam G may be formed between the plurality of the unit modules 30A-30L assembled with each other, but the light generated from the plurality of inorganic light emitting diodes 50 may be blocked by the black molding layer 100 covering the side surfaces 50b of the inorganic light emitting diodes 50 and thus the seam G may be not seen from the outside of the display apparatus 1. That is, without a separate process for removing the seam G between the plurality of the unit modules 30A-30L, it is possible to prevent the seam G from being conspicuous to a user.

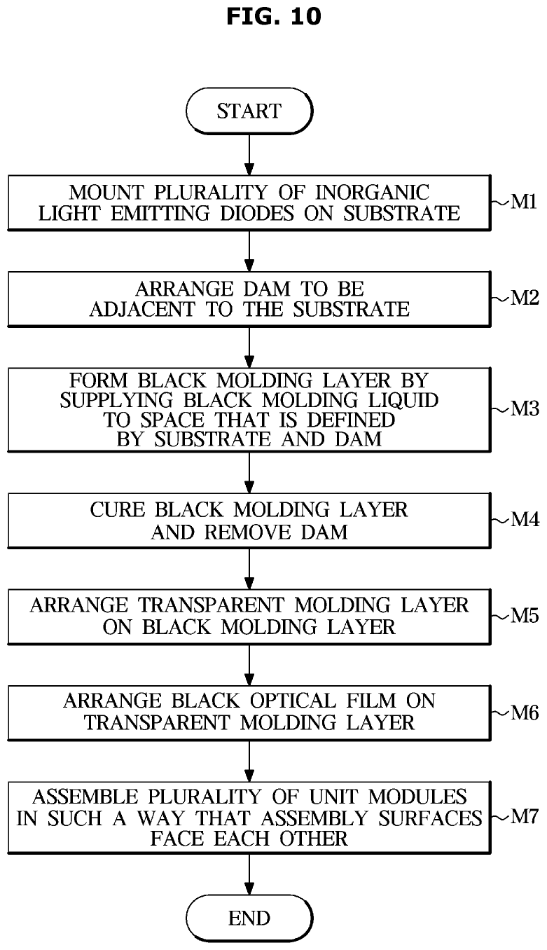

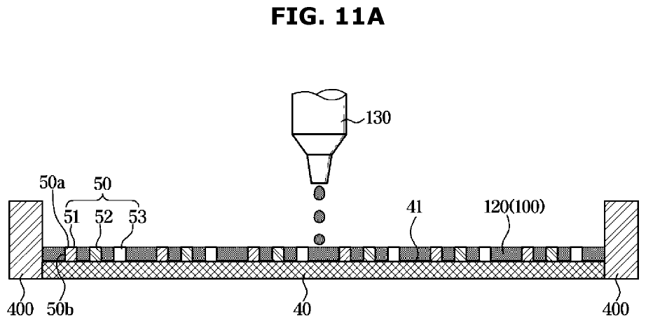

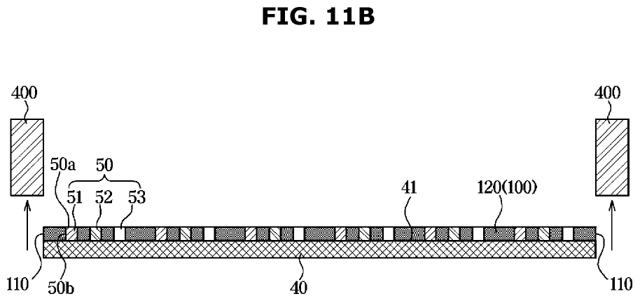

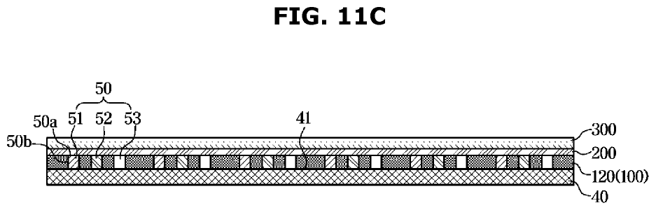

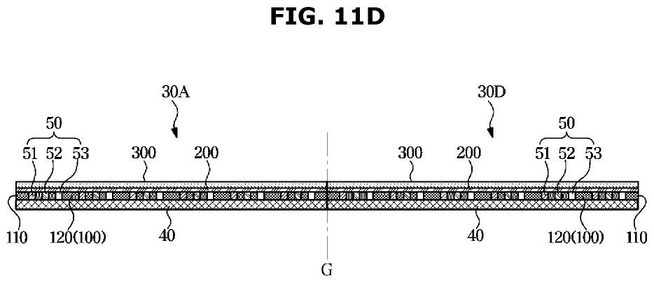

FIG. 10 is a flow chart illustrating a fourth manufacturing method of the display apparatus according to an embodiment of the disclosure and FIGS. 11A to 11D are views illustrating a manufacturing process according to the fourth manufacturing method of FIG. 10. The fourth manufacturing method of the display apparatus 1 is a method of manufacturing the display apparatus 1 by assembling a plurality of unit modules 30A-30L manufactured by the first manufacturing method of the display apparatus 1. Hereinafter, for convenience of description, the plurality of unit modules 30A-30L manufactured by the first manufacturing method of the display apparatus 1 will be mainly described, but alternatively may be manufactured by the second manufacturing method of the display apparatus 1. Hereinafter, FIGS. 1 to 5E may be referred to for reference numerals not shown in FIGS. 11A to 11D. Hereinafter, a case where the unit module 30A and the unit module 30D are assembled will be described as an example.

As illustrated in FIG. 10, a manufacturing method of the display apparatus 1 may include mounting the plurality of inorganic light emitting diodes 50 on the substrate 40 (M1). In this case, the first contact electrode 58 and the second contact electrode 59 of the plurality of inorganic light emitting diodes 50 may be connected to the electrodes 42 of the substrate 40 through soldering.

As illustrated in FIGS. 10 and 11A, the manufacturing method of the display apparatus 1 may further include arranging a dam 400 to be adjacent to the substrate 40 (M2). The dam 400 may be arranged in close contact with opposite ends of the substrate 40.

As illustrated in FIGS. 10 and 11A, the manufacturing method of the display apparatus 1 may further include forming the black molding layer 100 by supplying the black molding liquid 120 to a space that is defined by the substrate 40 and the dam 400 (M3). The black molding liquid 120 may be supplied on the substrate 40 in such a way that the black molding liquid 120 surrounds the side surfaces 50b of the plurality of inorganic light emitting diodes 50 and the front light emitting surfaces 50a are exposed.

As illustrated in FIGS. 10 and 11B, the manufacturing method of the display apparatus 1 may further include curing the black molding layer 100 and removing the dam 400 (M4). The assembly surface 110 of the plurality of unit modules 30A-30L may be defined as one surface of the black molding layer 100 cured in contact with the dam 400. Therefore, the assembly surface 110 of the plurality of unit modules 30A-30L may have a shape corresponding to the dam 400. The assembly surface 110 of the plurality of unit modules 30A-30L may have a flat shape.

As illustrated in FIGS. 10 and 11C, the manufacturing method of the display apparatus 1 may further include arranging the transparent molding layer 200 on the black molding layer 100 (M5).

As illustrated in FIGS. 10 and 11C, the manufacturing method of the display apparatus 1 may further include arranging the black optical film 300 on the transparent molding layer 200 (M6).

As illustrated in FIGS. 10 and 11D, the manufacturing method of the display apparatus 1 may further include assembling the plurality of unit modules 30A-30L such that the respective assembly surfaces 110 faces each other (M7). A description thereof is the same as those shown in FIG. 5D and thus it will be omitted.

As is apparent from the above description, by arranging the black molding layer having the low refractive index on the substrate to surround the inorganic light emitting diode, it is possible to improve the bonding reliability of the inorganic light emitting diode and to effectively reduce the speckle noise.

When the black molding layer is formed to surround the side surface of the inorganic light emitting diode, light generated from the inorganic light emitting diode may be blocked by the black molding layer and thus it is difficult for the light to be emitted to the outside of the display apparatus through the side surface of the inorganic light emitting diode. Therefore, it is possible to expect an effect of reducing the right and left viewing angles of the display apparatus, and it is possible to effectively prevent the seam between the unit modules adjacent to each other, from being seen.

Although a few embodiments of the present disclosure have been shown and described, it would be appreciated by those skilled in the art that changes may be made in these embodiments without departing from the principles and spirit of the disclosure, the scope of which is defined in the claims and their equivalents.

What is claimed is:

1. A manufacturing method of a display apparatus comprising:
mounting a plurality of inorganic light emitting diodes on a substrate;
forming a black molding layer having a low refractive index and configured to surround the plurality of inorganic light emitting diodes such that front light emitting surfaces of the plurality of inorganic light emitting diodes that are directed to a front side of the display apparatus are exposed; and
assembling a plurality of unit modules each comprising the substrate, the plurality of inorganic light emitting diode, and the black molding layer to be adjacent to each other.

2. The manufacturing method of claim 1, wherein
side surfaces of the plurality of inorganic light emitting diodes are covered with the black molding layer.

3. The manufacturing method of claim 1, wherein
the black molding layer has a refractive index of 1.40 or more and 1.58 or less.

4. The manufacturing method of claim 1, wherein
the black molding layer comprises at least one of a thermosetting material and a photosensitive material.

5. The manufacturing method of claim 4, wherein
the thermosetting material comprises at least one of silicon, epoxy, ethylene-vinyl acetate copolymer (EVA), polyvinyl butyral (PVB), and urethane.

6. The manufacturing method of claim 1, wherein
a width and a length of the plurality of inorganic light emitting diodes each has a size of several micrometers to several hundreds of micrometers.

7. The manufacturing method of claim 1, wherein
a first contact electrode and a second contact electrode of the plurality of inorganic light emitting diodes are connected to electrodes of the substrate through soldering.

8. The manufacturing method of claim 1, wherein the forming the black molding layer comprises: forming the black molding layer by supplying a black molding liquid onto the substrate; and
curing the black molding layer.

9. The manufacturing method of claim 1, wherein the forming the black molding layer comprises: forming the black molding layer by arranging a black film on the substrate to cover the plurality of inorganic light emitting diodes; and
allowing the black molding layer to be exposed to light such that the front light emitting surfaces of the plurality of inorganic light emitting diodes are exposed to outside.

10. The manufacturing method of claim 1, further comprising
arranging a transparent molding layer on the black molding layer to protect the plurality of inorganic light emitting diodes.

11. The manufacturing method of claim 10, further comprising
arranging a black optical film on the transparent molding layer to improve optical characteristics of the plurality of inorganic light emitting diodes.

12. The manufacturing method of claim 1, further comprising:
forming the black molding layer to cover the substrate;
forming assembly surfaces of the plurality of unit modules by cutting a spare portion of the black molding layer that is placed out of the substrate; and
assembling the plurality of unit modules such that the assembly surfaces face each other.

13. The manufacturing method of claim 1, further comprising:
arranging a dam to be adjacent to the substrate; and
forming the black molding layer in a space that is defined by the substrate and the dam.

14. The manufacturing method of claim 13, further comprising:
curing the black molding layer;
removing the dam; and
assembling the plurality of unit modules such that assembly surfaces of the plurality of unit modules formed by the dam face each other.

15. The manufacturing method of claim 1, wherein the assembling the plurality of unit modules to be adjacent to each other comprises arranging the plurality of unit modules in a matrix form.

16. A display apparatus comprising:
a plurality of unit modules; and
a frame configured to support the plurality of unit modules,
wherein each of the plurality of unit modules comprises:
a substrate;
a plurality of inorganic light emitting diodes mounted on the substrate; and
a black molding layer having a low refractive index and configured to surround side surfaces of the plurality of inorganic light emitting diodes such that light generated by the plurality of inorganic light emitting diodes is emitted through front light emitting surfaces of the plurality of inorganic light emitting diodes that are directed to a front side of the display apparatus.

17. The display apparatus of claim 16, wherein
the black molding layer has a refractive index of 1.40 or more and 1.58 or less.

18. The display apparatus of claim 16, wherein
the black molding layer comprises at least one of a thermosetting material and a photosensitive material.

19. The display apparatus of claim 16, wherein
a width and a length of the plurality of inorganic light emitting diodes each has a size of several micrometers to several hundreds of micrometers.

20. The display apparatus of claim 16, wherein
the plurality of unit modules are assembled to each other and are arranged in a matrix form.
